(19) United States
(12) Patent Application Publication
(10) Pub. No.: US 2009/0226009 A1
(43) Pub. Date: Sep. 10, 2009

(54) DEVICE AND METHOD

(75) Inventors: Carel HUYTS, Oldenzaal (NL); Ap OOST, Erica (NL)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 12/044,110

(22) Filed: Mar. 7, 2008

(51) Int. Cl. H03G 3/00

(52) U.S. Cl. 381/107

(57) ABSTRACT

The invention is directed towards a method in a portable hands free device. The method adjusts the sound level of a portable electronic device. The portable hands free device is adapted to be connected to the portable electronic device. The portable electronic device is adapted to generate sound. The method comprises obtaining a measurement of the environmental sound level surrounding the portable hands free device. The method also comprises sending a signal to the portable electronic device. The signal comprises information for adjusting the sound level of the portable electronic device according to the obtained environmental sound level measurement. The invention is also directed towards a portable hands free device, a method in a portable electronic device and a portable electronic device.

### TECHNICAL FIELD

The present invention relates to a method in a portable hands free device, a portable hands free device, a method in a portable electronic device and a portable electronic device. More particularly, the present invention relates to a mechanism for adjusting the sound level of a portable electronic device.

### BACKGROUND OF THE INVENTION

Portable electronic devices, such as cordless and cellular telephones, pagers, wireless modems, wireless email devices, personal digital assistants (PDAs) with communication functions, MP3 players and other portable electronic devices are becoming increasingly commonplace. Some of these portable electronic devices may be configured to communicate with other devices over the wireless communications network. Users of these portable electronic devices typically take these devices with them anywhere they go, which allows these users to, for example, place phone calls, listen to music, check an appointment on a calendar, watch a movie, check email and/or access the Internet and the information available thereon using the portable electronic device.

However, the user of such portable electronic device may move between different environments with different environmental noise levels. A problem that then may occur is that the user do not properly hear sound emitted from the portable electronic device, such as e.g. a ring signal in case the portable electronic device has communication ability. A consequence may be that the user misses an incoming phone call because he/she does not perceive the ring signal due to the environmental noise level, in case the signal level is too low. Another possible consequence may be that the portable electronic device generates a disturbingly vociferous ring signal, which may be utterly disturbing, not to say annoying among the users immediate entourage and may cause irritation among these, in case the ring signal is too loud in comparison with the environmental noise level.

A well known solution to this problem is to provide the portable electronic device with pre defined profiles with sound levels adapted to different environments and/or situations. Such solution is provided in most known mobile phones of the main producers of mobile phones. Some non exhaustive examples of such profiles maybe “normal”, “outside”, “meeting”, “home”, “office” etc.

However, these profiles offer a rather inconvenient solution, as the user has to constantly change profile as he/she change environment in order to receive a properly adjusted ring signal. Also, the environmental noise level may vary considerably also when the user does not change environment at all. As an example, a user situated outside in an extensive park may at moments experience almost complete silence, while he/she in the subsequent moment may be almost knocked unconscious of the noise chock when suddenly being over flown by a jet plane.

Thus there is a need for facilitating the adjustment of the volume level of a portable electronic device.

In addition, as competition increases among manufacturers of portable electronic devices and portable hands free devices, there is a marketing need for new functions and features.

### SUMMARY

The objective of the invention is to provide an improved mechanism for facilitating the adjustment of the volume level of a portable electronic device.

According to a first aspect, the object is achieved by a method in a portable hands free device. The method adjusts the sound level of a portable electronic device. The portable hands free device is adapted to be connected to the portable electronic device. The portable electronic device is adapted to generate sound. The method comprises obtaining a measurement of the environmental sound level surrounding the portable hands free device. The method also comprises sending a signal to the portable electronic device. The signal comprises information for adjusting the sound level of the portable electronic device according to the obtained environmental sound level measurement.

According to a second aspect, the object is achieved by a portable hands free device. The portable hands free device is adapted to adjust the sound level of a portable electronic device. The portable electronic device is adapted by sending a signal to the portable electronic device. The signal comprises information for adjusting the sound level of the portable electronic device. The sound level is adjusted according to an obtained environmental sound level measurement. The portable hands free device comprises an obtaining unit. The obtaining unit is adapted to obtain a measurement of the environmental sound level surrounding the portable hands free device. The portable hands free device also comprises a send unit. The send unit is adapted to send the signal to the portable electronic device. The signal comprises information for adjusting the sound level of the portable electronic device according to the obtained environmental sound level measurement.

According to a third aspect, the object is achieved by a method in a portable electronic device. The method is a method for adjusting the sound level of the portable electronic device. The portable electronic device is adapted to generate sound. The portable electronic device is also adapted to be connected to a portable hands free device. The method comprises receiving a signal from the portable hands free device. The signal comprises information for adjusting the sound level of the portable electronic device. The method further comprises the step of adjusting the sound level according to the received signal.

According to a fourth aspect, the object is achieved by a portable electronic device. The portable electronic device comprises a receptor. The receptor is adapted to receive a signal from the portable hands free device. Also, the portable electronic device comprises a sound generator. The sound generator is adapted to generate a sound at a sound level. Further, the portable electronic device comprises a sound level adjustment unit. The sound level adjustment unit is adapted to adjust the sound level of the portable electronic device according to the information comprised in the signal received from the portable hands free device.

Thanks to the measurement of the environmental noise level, the sound level of a sound, such as a ring signal, may be adapted to the environmental noise level, without further adjustments or fine tuning from the user. Thereby it is possible to eliminate or at least reduce the risk of loosing a telephone call due to unattended telephone signals. Thus an improved mechanism for facilitating the adjustment of the volume level of a portable electronic device has been achieved.

An advantage with the present methods and devices is that the sound level of a ring signal may be adapted to the environmental sound/noise level automatically, without further efforts from the user.

Yet an advantage with the present methods and devices is that the sound level of a speech may be adapted to the environmental sound/noise level automatically.

### BRIEF DESCRIPTION OF THE DRAWINGS

The present invention will now be described more in detail in relation to the enclosed drawings, in which:

FIG. 1 is a schematic block diagram illustrating a portable electronic device with an attached portable hands free device.

FIG. 2 is a three dimensional view depicting an embodiment of a portable hands free device attached via a wireless connection to a portable electronic device.

FIG. 3 is a flow chart depicting a method in a portable hands free device for adjusting the sound level of a portable electronic device.

FIG. 4 is a block diagram depicting a portable hands free device.

FIG. 5 is a flow chart depicting a method in a portable electronic device for adjusting the sound level of the portable electronic device.

FIG. 6 is a block diagram depicting a portable electronic device.

### DETAILED DESCRIPTION OF PREFERRED EMBODIMENTS

The invention is defined as a method in a portable hands free device, a portable hands free device, a method in a portable electronic device and a portable electronic device, which may be put into practice in the embodiments described below. This invention may, however, be embodied in many different forms and should not be construed as limited to the embodiments set forth herein; rather, these embodiments are provided so that this disclosure will be thorough and complete, and will fully convey the scope of the invention to those skilled in the art. It should be understood that there is no intent to limit the present method in a portable hands free device, a portable hands free device, a method in a portable electronic device and a portable electronic device to any of the particular forms disclosed, but on the contrary, the present method in a portable hands free device, portable hands free device, method in a portable electronic device and portable electronic device is to cover all modifications, equivalents, and alternatives falling within the scope of the invention as defined by the claims.

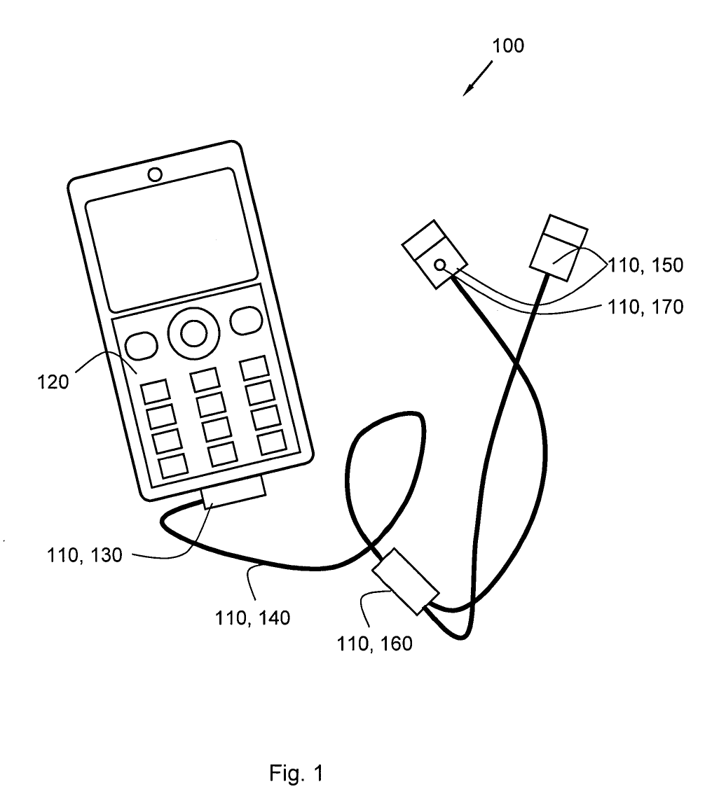

FIG. 1 is a schematic illustration over a portable arrangement 100 comprising a portable hands free device 110 attached to a portable electronic device 120. The portable hands free device 110 may be attached to the portable electronic device 120 via a port 130. The port 130 represents an interface between the portable hands free device 110 and the portable electronic device 120. The port 130 thus comprises one part comprised within the portable hands free device 110 and one part comprised within the portable electronic device 120. The port 130 may be linked with a connection 140. The connection 140 may according to some embodiments be wireless, comprising e.g. a Bluetooth connection. Alternatively, according to some embodiments, the connection 140 may be a wired connection as illustrated in the example in FIG. 1. The portable hands free device 110 may according to some embodiments comprise a microphone 160.

According to some embodiments, at least one earphone house 150 may be adapted to be situated into at least one ear of a user. In at least one of the earphone houses 150, may a sound level meter 170 be attached according to some embodiments. However, according to some embodiments the sound level meter 170 may be attached to any other part of the portable hands free device 110, such as e.g. in the proximity of the microphone 160 or within any part of the body of the portable hands free unit 110.

The portable electronic device 120 as herein described may in some embodiments comprise a portable communication device such as a mobile station e.g. a mobile cellular telephone. However, as used herein, a “portable electronic device” may include devices having only a wireless signal receiver without transmit abilities and devices having both receive and transmit hardware capable of two-way communication over a two-way communication link as well as devices without any communication ability at all. The portable electronic device 120 may according to some embodiments be a Personal Digital Assistant (PDA), a music player such as e.g. an MP3 player, a radio, a digital audio player, an iPod, a portable media player, a portable multimedia player, a portable video player (PVP), a Compact Disc (CD) player, a laptop, a wireless email device, a digital video camera, a handheld game console, a Geiger meter, or any other kind of portable electronic device, such as e.g. a notebook computer, a PC speaker, a loud speaker, an avalanche transceiver, un Appareil de Recherche de Victimes en Avalanche (ARVA), an air raid siren, a tornado siren, an outdoor warning siren, a fire alarm, a pager, a beeper, a buzzer, an electric bell, a walkie-talkie, a hunting radio, a baby monitor etc.

Further, the portable electronic device 120 may be adapted to communicate within a wireless communication system to a recipient, according to same embodiments. The portable electronic device 120 may be adapted to communicate e.g. in Code Divisional Multiple Access (CDMA), Wideband Code Division Multiple Access (WCDMA), cdma2000, High Speed Packet Data Access (HSPA), High Speed Downlink Packet Data Access (HSDPA) Fraction High Speed Downlink Packet Data Access (F-HSDPA), High Speed Uplink Packet Data Access (HSUPA), Universal Mobile Telecommunications System (UMTS), Long Term Evolution (LTE), or according to any other wireless or wired communication standard.

The portable hands free device 110 may be e.g. an in-concha headset, adapted to be carried in the concha of the ear. However, according to some embodiments, the portable hands free device 110 may be an in-ear headset, adapted to be carried in the auditory meatus of the ear. The portable hands free device 110 may further comprise various means for attaching the portable hands free device 110 to the ear and/or head and/or neck of a user. According to yet some embodiments, the portable hands free device 110 may be carried around the wrist of the user, embodied e.g. as a watch. According to other embodiments, the portable hands free device 110 may be attached to a belt, carried around the user's body. According to still some embodiments, the portable hands free device 110 may be adapted to be carried around the user's neck, in a manner similar to how a necklace is carried. According to yet some embodiments, the portable hands free device 110 may be adapted to be attached to the user's glasses/sunglasses.

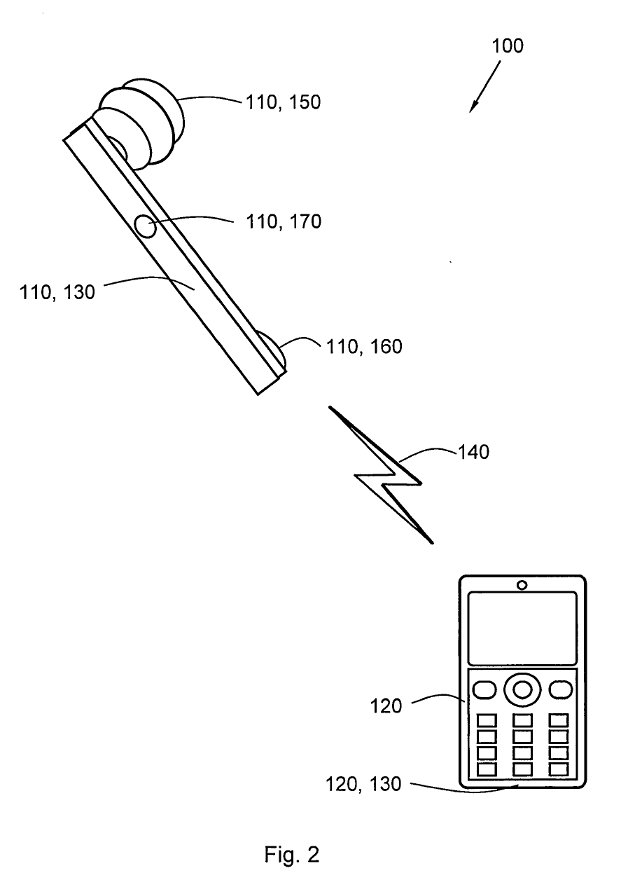

FIG. 2 schematically depicts an embodiment of a portable arrangement 100 comprising a portable hands free device 110 and a portable electronic device 120. The portable hands free device 110 may be attached to the portable electronic device 120 via a port 130. The port 130 represents an interface between the portable hands free device 110 and the portable electronic device 120. The port 130 thus comprises one part comprised within the portable hands free device 110 and one part comprised within the portable electronic device 120. The port 130 may be linked with a connection 140. The connection 140 may according to some embodiments be wireless, comprising e.g. a Bluetooth connection as illustrated in the example in FIG. 2. The wireless connection 140 between the portable hands free device 110 and the portable electronic device 120 may however, according to some embodiments be represented by the emission of any other kind of electro magnetic waves carrying a signal over part or the entire communication path 140, such as e.g. radio waves or infra red light. The wireless connection 140 may comprise a Wireless Personal Area Network (WPAN), comprising technologies such as e.g. Infrared Data Association (IrDA), Bluetooth, Ultra-wideband (UWB), and ZigBee. Further, the wireless connection 140 may be adapted to a wireless personal area networks standard such as e.g. IEEE 802.15.4.

The portable hands free device 110 may according to some embodiments comprise a microphone 160. Also, the portable hands free device 110 may comprise, according to some embodiments, at least one earphone house 150 which may be adapted to be situated into at least one ear of a user. According to some embodiments, the portable hands free device 110 may comprise two earphone houses 150.

The portable hands free device 110 further comprises a sound level meter 170 adapted to measure the perceived environmental sound level surrounding the portable hands free device 110. The noise of the environment may be perceived by the microphone 160 and converted into electrical signals, which may be interpreted as corresponding to a certain environmental noise level by the sound level meter 170. The sound level meter 170 may according to some embodiments comprise logic for comparing the environmental noise level with a norm or scale. Mentioned as a non limiting example only, the environmental noise level may be leveled with a number between 0 and 10, where 5 is an average background noise level. Further, the portable hands free device 110 may, according to some embodiments, comprise logic for comparing the perceived environmental noise level with the sound level of the portable electronic device 120. Also, according to some embodiments, the portable hands free device 110 may be adapted to generate commands for increasing or decreasing the sound level of the portable electronic device 120, according to the outcome of the comparison.

The advantage of such a solution provided within the portable hands free device 110 is that a user may achieve the automatic sound level adjustment according to the present methods on an existing portable electronic device 120. Thus he/she does not need to change portable electronic device 120, but only complete it with a portable hands free device 110 according to the present solution.

However, according to some embodiments, the logic for comparing the perceived environmental noise level with the sound level of the portable electronic device 120 may be comprised within the portable electronic device 120. According to these embodiments, the portable hands free device 110 only sends a signal comprising a representation of the perceived environmental noise level to the portable electronic device 120.

An advantage of such a solution is that the portable hands free device 110 may be produced with less cost, effort, energy consumption and with less environmental pollution, which may save resources.

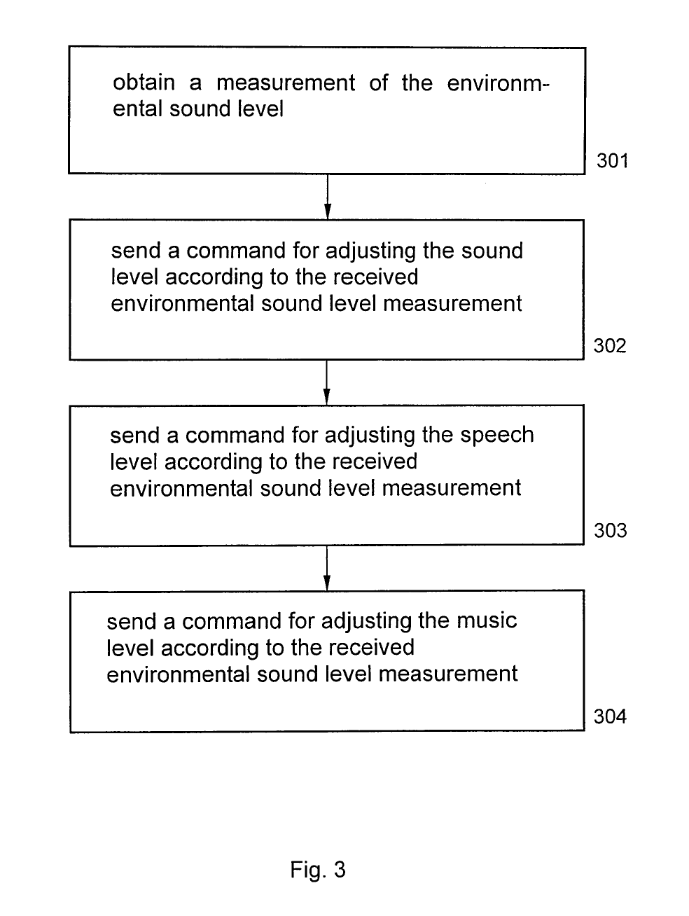

FIG. 3 is a flow chart illustrating embodiments of method steps 301-304. The method steps 301-304 are comprised within a method in the portable hands free device 110. The method aims at adjusting the sound level of a portable electronic device 120. The portable hands free device 110 is adapted to be connected to the portable electronic device 120. The portable electronic device 120 is adapted to generate sound.

To appropriately adjusting the sound level of a portable electronic device 120, the method may comprise a number of steps 301-304. It is however to be noted that some of the described method steps are optional and only comprised within some embodiments. Further, it is to be noted that the method steps 301-304 may be performed in any arbitrary chronological order and that some of them, e.g. step 301 and step 302, or even all steps may be performed simultaneously or in an altered, arbitrarily rearranged, decomposed or even completely reversed chronological order. The method may comprise the following steps:

### Step 301

A measurement of the environmental sound level surrounding the portable hands free device 110 is obtained. The measurement is obtained by measuring the environmental sound level of the environment surrounding the portable hands free device 110. According to some embodiments, the environmental noise level may be perceived by the microphone 160 which may be comprised within the portable hands free device 110. The measured noise level may be obtained by the sound level meter 170 and converted into electrical signals, which may be interpreted as corresponding to a certain environmental noise level by the sound level meter 170.

The measurement of the environmental sound level surrounding the portable hands free device 110 may, according to some embodiments, be obtained continuously or at certain intervals. The length of such intervals may vary. The measurement of the environmental sound level may also be made when a command is received from the portable electronic device 120, according to some embodiments.

### Step 302

The portable hands free device 110 sends a signal to the portable electronic device 120. The signal comprises information for adjusting the sound level of the portable electronic device 120, according to the obtained environmental sound level measurement. According to some embodiments, the signal may comprise a command for increasing and or decreasing the sound level. According to some embodiments, the signal may comprise information concerning the intensity of the perceived environmental noise level, or an estimation of the environmental noise level such as e.g. a number on a scale.

The sound level of the portable electronic device 120 to be adjusted may be a ring signal of the portable electronic device 120. The ring signal may be activated when a telephone call, message or similar is received at the portable electronic device 120. However, the sound level to be adjusted may also be an alert signal, an alarm signal, a frequency signal or other indicative signal which sound in itself may communicate meaningful information to a user.

### Step 303

This step is optional and may be performed only according to some embodiments. The portable hands free device 110 may send a signal to the portable electronic device 120. The signal may comprise information for adjusting the speech level of the portable electronic device 120 according to the obtained environmental sound level measurement. Thus the speech level of the portable electronic device 120, e.g. a mobile phone, may be adjusted automatically, without further fine tuning by the user.

According to some embodiments, the signal may comprise a command for increasing and or decreasing the speech level. According to some embodiments, the signal may comprise information concerning the intensity of the perceived environmental noise level, or an estimation of the environmental noise level such as e.g. a number on a scale.

### Step 304

Step 304 is optional and may be performed only according to some embodiments. The portable hands free device 110 may send a signal to the portable electronic device 120. The signal may comprise information for adjusting the music level of the portable electronic device 120 according to the obtained environmental sound level measurement. Thus the music level may be increased when the environmental noise level increase, and vice versa. According to some embodiments, a tinnitus barrier may be arranged, in order to prevent a hearing disorder to evolve. Thus the music level may be barred from increasing over a certain level in order to prevent impaired hearing.

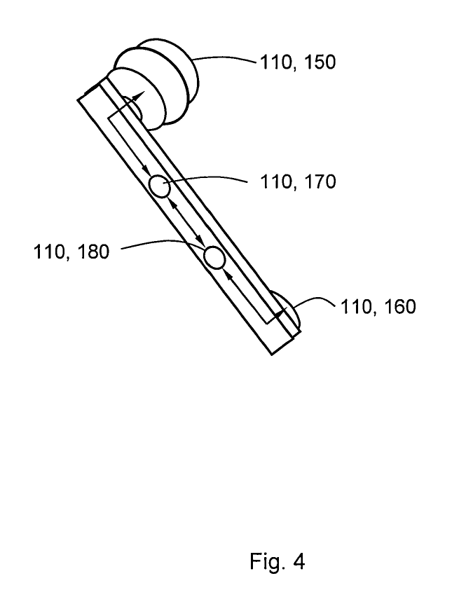

FIG. 4 is an illustration over a portable hands free device 110, according to the present solution. The portable hands free device 110 is adapted to adjust the sound level of a portable electronic device 120. The portable hands free device 110 is adapted to be connected to the portable electronic device 120. The portable electronic device 120 is adapted to generate sound. The sound level in the portable device is adjusted by sending a signal to the portable electronic device 120. The signal may be send over a connection 140 between the portable hands free device 110 and the portable electronic device 120. The connection 140 may be wired, according to some embodiments. However, according to some embodiments, the connection 140 may be a wireless connection, such as e.g. a Bluetooth connection. Thus, according to some embodiments, the portable hands free device 110 may be adapted to send the signal via a wireless connection 140. The wireless connection 140 may be a Bluetooth connection, according to some embodiments.

For the sake of clarity and in order not to render unnecessary aggravating circumstances for the uninitiated reader to comprehend the present method and portable hands free device 110, any internal electronics of the portable hands free device 110, not necessary for performing the present method has been omitted from FIG. 4.

The signal comprises information for adjusting the sound level of the portable electronic device 120. The sound level of the portable electronic device 120 is adjusted according to an obtained environmental sound level measurement. The portable hands free device 110 comprises a sound level meter 170. The sound level meter 170 is adapted to obtain a measurement of the environmental sound level surrounding the portable hands free device 110. The sound level meter 170 may, according to some embodiments be adapted to measure the perceived environmental sound level surrounding the portable hands free device 110.

The portable hands free device 110 also comprises a send unit 180. The send unit 180 is adapted to send a signal to the portable electronic device 120. The signal comprises information for adjusting the sound level of the portable electronic device 120. The adjustment is thus made according to the obtained environmental sound level measurement.

It is to be noted that the described units 130-180 comprised within the portable hands free device 110 are to be regarded as separate logical entities but not with necessity separate physical entities. Any, some or all of the units 130-180 may be comprised or co-arranged within the same physical unit. However, in order to facilitate the understanding of the functionality of the portable hands free device 110, the comprised units 130-180 are illustrated as separate physical units in FIG. 4.

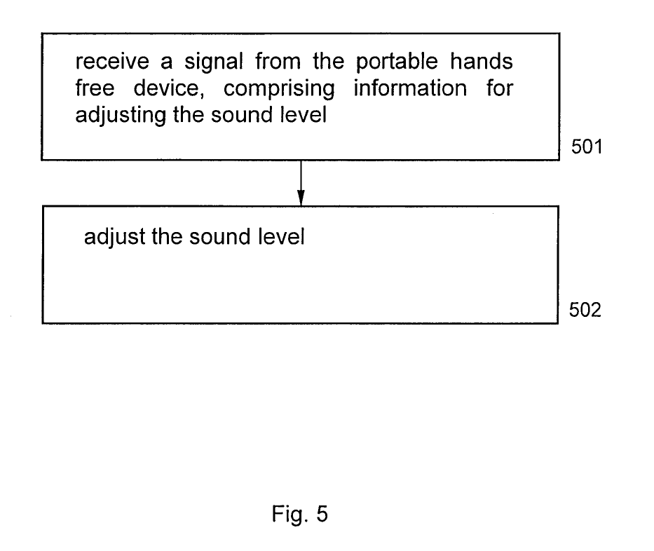

FIG. 5 is a flow chart illustrating embodiments of method steps 501-502. The method steps 501-502 are comprised within a method in the portable electronic device 120. The method aims at adjusting the sound level of the portable electronic device 120. The portable electronic device 120 is adapted to generate sound, such as e.g. a ring signal. The portable electronic device 120 is further adapted to be connected to a portable hands free device 110.

To appropriately adjusting the sound level of the portable electronic device 120, the method may comprise a number of steps 501-502. It is however to be noted that some of the described method steps are optional and only comprised within some embodiments. Further, it is to be noted that the method steps 501-502 may be performed in any arbitrary chronological order and that some of them, e.g. step 501 and step 502, or even all steps may be performed simultaneously or in an altered, arbitrarily rearranged, decomposed or even completely reversed chronological order. The method may comprise the following steps:

### Step 501

The portable electronic device 120 receives a signal from the portable hands free device 110, which signal comprises information for adjusting the sound level of the portable electronic device 120.

The sound level of the portable electronic device 120 to be adjusted may be a ring signal of the portable electronic device 120. The ring signal may be activated when a telephone call, message or similar is received at the portable electronic device 120. However, the sound level to be adjusted may also be an alert signal, an alarm signal, a frequency signal or other indicative signal which sound in itself may communicate meaningful information to a user.

In that way, it is possible to effortless for the user, automatically adapt the sound level of the ring signal of the portable electronic device 120. If the presence of a complete silence is detected, the portable electronic device 120 may even be put into mute mode, with only the vibrator active.

According to some embodiments, the sound level of the portable electronic device 120 to be adjusted may be the speech level of the portable electronic device 120.

The signal thus may comprise information for adjusting the speech level of the portable electronic device 120 according to the obtained environmental sound level measurement. Thus the speech level of the portable electronic device 120, e.g. a mobile phone, may be adjusted automatically, without further fine tuning by the user.

According to some embodiments, the signal thus may comprise a command for increasing and or decreasing the speech level. According to some embodiments, the signal may comprise information concerning the intensity of the perceived environmental noise level, or an estimation of the environmental noise level such as e.g. a number on a scale.

The sound level of the portable electronic device 120 to be adjusted may be a music level of the portable electronic device 120, according to some embodiments.

According to these embodiments, the signal may comprise information for adjusting the music level of the portable electronic device 120 according to the obtained environmental sound level measurement. Thus the music level may be increased when the environmental noise level increase, and vice versa. According to some embodiments, a tinnitus barrier may be arranged, in order to prevent a hearing disorder to evolve. Thus the music level may be barred from increasing over a certain level in order to prevent impaired hearing.

### Step 502

The sound level is adjusted according to the received signal. As previously discussed, the sound level may be the sound level of a ring signal, a speech level, a music level, or an arbitrary combination of these and/or other sound levels.

The adjustment is made such that the sound level is increased if an increased environmental noise level is detected. Correspondingly the sound level is decreased if an decreased environmental noise level is detected. If the environmental noise level is identified as a silence, the ring signal may, according to some optional embodiments, be set into mute mode with only a vibrator signal activated.

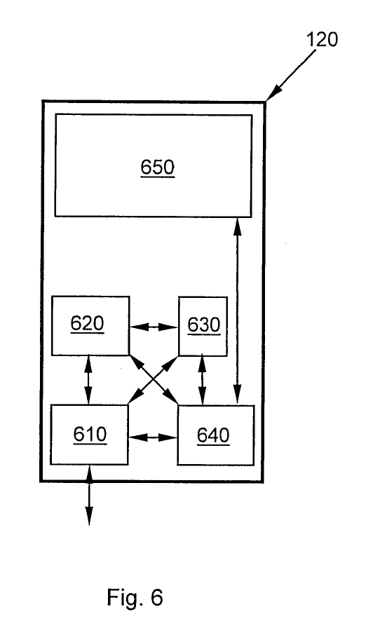

FIG. 6 is an illustration over a portable electronic device 120, according to the present solution. The portable electronic device 120 comprises a sound generator 620 adapted to generate a sound at a sound level. The sound generator 620 may be represented by a loud speaker and the sound may be a ring signal. Further, the portable electronic device 120 comprises a receptor 610. The receptor 610 is adapted to receive a signal from the portable hands free device 110. The receptor 610 may be represented by a receiver, a transceiver or similar unit for receiving signals. Still further, the portable electronic device 120 comprises a sound level adjustment unit 630. The sound level adjustment unit 630 is adapted to adjust the sound level of the portable electronic device 120. The sound level of the portable electronic device 120 is adjusted according to the information comprised in the signal received from the portable hands free device 110.

According to some embodiments, the portable electronic device 120 may comprise a logical unit 640. The logical unit 640 may be adapted to compare the received signal information for adjusting the sound level of the portable electronic device 120 with the present sound level of the portable electronic device 120. The logical unit 640 may comprise a processing unit such as e.g. a Central Processing Unit (CPU), a microprocessor, a Peripheral Interface Controller (PIC) microcontroller or any other appropriate device adapted to interpret computer program instructions and processes data. The logical unit 640 may further be connected to a memory unit 650.

The memory unit 650 may be a primary storage memory unit such as a processor register, a cache memory, a Random Access Memory (RAM) or similar. The memory unit 650 may however in some embodiments be a secondary memory unit such as a Read Only Memory (ROM), Electrically Erasable Programmable Read-Only Memory (EEPROM), programmable read-only memory (PROM) or erasable programmable read-only memory (EPROM) or a hard disk drive. The memory unit 650 may however in some embodiments be an off-line storage memory unit, a flash memory, a USB memory or a memory card. The memory unit 650 may in some embodiments be a Network-attached storage (NAS) or in fact any other appropriate medium such as a disk or a tape that can hold machine readable data.

For the sake of clarity and in order not to render unnecessary aggravating circumstances for the uninitiated reader to comprehend the present method and portable electronic device 120, any internal electronics of the portable electronic device 120, not necessary for performing the present method according to step 501-503 has been omitted from FIG. 6.

It is to be noted that the described units 610-650 comprised within some embodiments of the portable electronic device 120 are to be regarded as separate logical entities but not with necessity separate physical entities. Any, some or all of the units 610-650 may be comprised or co-arranged within the same physical unit. However, in order to facilitate the understanding of the functionality of the portable electronic device 110, the comprised units 610-650 are illustrated as separate physical units in FIG. 6.

### Computer Programs

The methods for adjusting the sound level of a portable electronic device 120, according to the present methods may be implemented through one or more processors 640 in the portable electronic device 120, or in the portable hands free device 110, together with computer program code for performing the functions of the methods. The program code mentioned above may also be provided as a computer program product, for instance in the form of a data carrier carrying computer program code for performing the methods according to the present solution when being loaded into the processor unit 640. The data carrier may be a CD ROM disc, a memory stick, or any other appropriate medium such as a disk or tape that can hold machine readable data. The computer program code may furthermore be provided as pure program code on a server and downloaded to portable electronic device 120 and/or the portable hands free device 110 remotely.

Thus a computer program comprising instruction sets for performing the method according to steps 301-304 or the method according to steps 501-503 may be used for implementing the previously described methods.

As will be appreciated by one of skill in the art, the present invention may be embodied as a portable electronic device 120, a portable hands free device 110, a method in a portable electronic device 120, a method in a portable hands free device 110 or computer program products. Accordingly, the present invention may take the form of an entirely hardware embodiment, a software embodiment or an embodiment combining software and hardware aspects all generally referred to herein as a “circuit” or “module.”Furthermore, the present invention may take the form of a computer program product on a computer-usable storage medium having computer-usable program code embodied in the medium. Any suitable computer readable medium may be utilized including hard disks, CD-ROMs, optical storage devices, a transmission media such as those supporting the Internet or an intranet, or magnetic storage devices.

Computer program code for carrying out operations of the present methods may be written in any arbitrary programming language such as Java®, Smalltalk or C++. However, the computer program code for carrying out the steps of the present method may also be written in any conventional procedural programming languages, such as the “C” programming language and/or a lower level assembler language. The program code may execute entirely on the user's portable electronic device 120, partly on the user's portable electronic device 120, as a stand-alone software package, partly on the user's portable electronic device 120 and partly on a remote computing device or entirely on the remote computing device. In the latter scenario, the remote computing device may be connected to the user's portable electronic device 120 through a local area network (LAN) or a wide area network (WAN), or the connection may be made to an external computer, for example, through the Internet using an Internet Service Provider.

Furthermore, the present methods were described in part above with reference to flowchart illustrations and/or block diagrams of a portable electronic device 120, portable hands free device 110, methods, and computer program products according to embodiments of the invention. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

### Further Applications of the Present Methods and Devices

An advantage of the present methods and devices is that the risk of missing a telephone call due to a too low ring signal may be reduced, thanks to the automatic adaptation of the ring signal level to the environmental background noise level.

Also the risk of unnecessarily disturb the environment due to a too high ring signal may be reduced, or even eliminated, as the ring signal level thanks to the invented method is automatically reduced or even set into mute mode when a very low environmental sound level, silence, is detected.

Another advantage according to some embodiments of the present methods and devices may be to adjust the speech level automatically, when calling a telephone call, in analogy with the above explained mechanism for adjusting the ring signal level automatically.

According to some embodiments, the present methods and devices may be used for adjusting the music played on the portable electronic device 120, such that it is presented to user load enough to be heard over the environmental noise.

The present methods and devices may, according to some embodiments be used as a sound detector. The portable hands free device 110 may be set into sound detection mode. When an environmental sound level above a certain trigger level, which may be adjustable for the user, is perceived, an alarm signal may be sent to the portable electronic device 120. The portable electronic device 120 may in turn communicate to a communication device carried by the user, such as e.g. sending an SMS to a mobile phone carried by the user.

The present methods and devices may, according to some embodiments be used as a burglar alarm. The portable hands free device 110 may be set into burglar alarm mode. When an environmental sound level above a certain trigger level, which may be adjustable for the user, is perceived, an alarm signal may be sent to the portable electronic device 120. The portable electronic device 120 may be activated in silent burglar alarm mode or burglar alarm mode. When the portable electronic device 120 is set into silent burglar alarm mode, the portable electronic device 120 may communicate to a communication device carried by the user, such as e.g. sending an SMS to a mobile phone carried by the user. When the portable electronic device 120 is set into burglar alarm mode, a siren signal may be activated.

The suggested burglar alarm mode functions may be useful in particular when the user is travelling e.g. in a hotel room, railway compartment or similar.

The present methods and devices may, according to some embodiments be used as a hunters support, for alerting the hunter e.g. when an animal is approaching a carrion. The portable hands free device 110 may be set into alarm mode. When an environmental sound level, which may be supposed to be generated by the animal, above a certain trigger level, which may be adjustable for the user, is perceived, an alarm signal may be sent to the portable electronic device 120. The portable electronic device 120 may be activated in silent alarm mode. When the portable electronic device 120 is set into silent burglar alarm mode, the portable electronic device 120 may communicate to a communication device carried by the hunter, such as e.g. sending an SMS to a mobile phone carried by the user. Thus the hunter may relax and/or hide in a hiding place until the game approach into firing range.

The terminology used in the detailed description of the particular exemplary embodiments illustrated in the accompanying drawings is not intended to be limiting of the invention. In the drawings, like numbers refer to like elements.

As used herein, the singular forms “a”, “an” and “the” are intended to include the plural forms as well, unless expressly stated otherwise. It will be further understood that the terms “includes,” “comprises,” “including” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that when an element is referred to as being “connected” or “coupled” to another element, it can be directly connected or coupled to the other element or intervening elements may be present. Furthermore, “connected” or “coupled” as used herein may include wirelessly connected or coupled. As used herein, the term “and/or” includes any and all combinations of one or more of the associated listed items.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

1. A method in a portable hands free device for adjusting the sound level of a portable electronic device, the portable hands free device is adapted to be connected to the portable electronic device, the portable electronic device being adapted to generate sound, the method comprises:
obtaining a measurement of the environmental sound level surrounding the portable hands free device,
sending a signal to the portable electronic device which signal comprises information for adjusting the sound level of the portable electronic device according to the obtained environmental sound level measurement.

2. A method according to claim 1, comprising the further step of:
sending a signal to the portable electronic device which signal comprises information for adjusting the speech level of the portable electronic device according to the obtained environmental sound level measurement.

3. A method according to claim 1, comprising the further step of:
sending a signal to the portable electronic device which signal comprises information for adjusting the music level of the portable electronic device according to the obtained environmental sound level measurement.

4. A method according to claim 1, wherein the portable hands free device is adapted to be connected to the portable electronic device via a wireless connection.

5. A portable hands free device adapted to adjust the sound level of a portable electronic device by sending a signal to the portable electronic device, which signal comprises information for adjusting the sound level of the portable electronic device, according to an obtained environmental sound level measurement, the portable hands free device comprises:
a sound level meter, adapted to obtain a measurement of the environmental sound level surrounding the portable hands free device,
a send unit adapted to send the signal to the portable electronic device which signal comprises information for adjusting the sound level of the portable electronic device according to the obtained environmental sound level measurement.

6. A portable hands free device according to claim 5, wherein:
the sound level meter comprises a sound level meter adapted to measure the perceived environmental sound level surrounding the portable hands free device.

7. A portable hands free device according to claim 5, wherein the portable hands free device is adapted to send the signal via a wireless connection.

8. A portable hands free device according to claim 5, wherein the wireless connection is a Bluetooth connection.

9. A method in a portable electronic device, for adjusting the sound level of the portable electronic device, the portable electronic device is adapted to generate sound and to be connected to a portable hands free device, the method comprises:
receiving a signal from the portable hands free device, which signal comprises information for adjusting the sound level of the portable electronic device, and;
adjusting the sound level according to the received signal.

10. A method in a portable electronic device according to claim 9, wherein:
the sound level to be adjusted is a ring signal.

11. A method in a portable electronic device according to claim 9, wherein:
the sound level to be adjusted is a speech level.

12. A method in a portable electronic device according to claim 9, wherein:
the sound level to be adjusted is a music level.

13. A portable electronic device, comprising:
a receptor adapted to receive a signal from the portable hands free device,
a sound generator adapted to generate a sound at a sound level, and
a sound level adjustment unit adapted to adjust the sound level of the portable electronic device according to the information comprised in the signal received from the portable hands free device.

14. A portable electronic device, according to claim 13, further comprising:
A logical unit adapted to compare the received signal information for adjusting the sound level of the portable electronic device with the present sound level of the portable electronic device.
